(19) United States
(12) Patent Application Publication
(10) Pub. No.: US 2014/0152313 A1
(43) Pub. Date: Jun. 5, 2014

(54) BATTERY SENSOR

(71) Applicant: ISABELLENHUETTE HEUSLER GMBH & CO. KG, Dillenburg (DE)

(72) Inventor: Ullrich HETZLER, Dillenburg-Oberscheld (DE)

(73) Assignee: ISABELLENHUETTE HEUSLER GMBH & CO. KG, Dillenburg (DE)

(21) Appl. No.: 13/692,184

(22) Filed: Dec. 3, 2012

(51) Int. Cl. G01R 31/36

(52) U.S. Cl. CPC G01R 31/3606; G01R 31/3624
USPC 324/426

(57) ABSTRACT

The invention relates to a battery sensor for a battery, in particular a motor vehicle battery, with a pole terminal (2) made out of an electrically conductive material for electric connection of the battery sensor (1) to a connecting contact of a battery, in particular to a ground contact of the battery, as well as with a low-ohm current-sense resistor for measuring a battery current with which the battery is discharged or charged. The battery sensor according to the invention further includes a plurality of tongues (8-10) arranged apart from the pole terminal (2) for mechanical mounting of the current-sense resistor (4) on the pole terminal (2). (FIG. 1)

The invention relates to a battery sensor for a battery, in particular for a motor vehicle battery.

In modern motor vehicle power networks, the battery current (charging current or discharge current) can be measured by means of a battery sensor which is integrated into the pole terminal which is connected to the ground pole of the motor vehicle battery. The actual measurement of the battery current usually takes place by means of a low-ohmic current-sense resistor (“shunt”) through which the battery current flows, so that the voltage drop over the low-ohmic current-sense resistor forms a measure for the battery current in accordance with Ohm's law. For example, a current-sense resistor as is known from EP 0 605 800 A1 may be used. Furthermore, an electronic measuring circuit can be integrated into the battery sensor, as is known for example from EP 1 363 131 A1 and EP 1 030 185 A2.

Problematic in the case of these known battery sensors is the mechanical loading which can arise in the case of improper use, if for example an installer would like to lift the motor vehicle battery out of the installation space at the ground cable, as the entire weight of the motor vehicle battery than has to be absorbed by the battery sensor.

Various possible designs of battery sensors are known from DE 10 2004 051 489 A1 and DE 10 2004 055 848 A1, in which the low-ohmic current-sense resistor forms an integral constituent of the pole terminal or is welded to the pole terminal. These known designs of a battery sensor are however relatively complex or not sufficiently mechanically loadable.

The object of the invention is therefore to provide a correspondingly improved battery sensor.

This object is achieved by a battery sensor according to the invention according to the main claim.

The battery sensor according to the invention is preferably designed for a motor vehicle battery, however the battery sensor according to the invention is also suitable for other battery types. Furthermore, it is to be pointed out that with regards to the battery, the invention is not limited to certain battery capacities and battery voltages and is fundamentally suitable both for chargeable batteries and for non-rechargeable batteries.

In compliance with the prior art, the battery sensor according to the invention also has a pole terminal made a from an electrically conductive material, wherein the pole terminal can be attached on a battery pole of the battery in order to produce an electrical and mechanical connection between the pole terminal and the battery pole. Preferably, the pole terminal is attached on the ground pole of the battery during operation, however it is also fundamentally possible to attach the pole terminal on the voltage pole of the battery.

Furthermore, the battery sensor according to the invention also has a low-ohmic current-sense resistor for measuring the battery current, wherein during operation the battery current flows through the current-sense resistor, so that the voltage drop over the low-ohmic current-sense resistor forms a measure for the battery current in accordance with Ohm's law. For example, in the context of the invention, a current-sense resistor as is described in EP 605 800 A1 may be used. The invention can however fundamentally also be realized using other types of current-sense resistors.

The invention then provides that the pole terminal has a plurality of tongues projecting from the pole terminal for mechanically holding the current-sense resistor. This type of mechanical holding of the current-sense resistor can offer greater mechanical loadability compared to the previously mentioned conventional designs.

The concept of a tongue used in the context of the invention preferably comprises an elongated holder which is preferably attached or molded on one side on the pole terminal. In the preferred exemplary embodiment of the invention, the tongues have a rectangular cross section in each case, but tongues with other cross sections are also possible in the context of the invention.

Preferably, the tongues are molded on one side onto the pole terminal and consist at the core of the same material as the pole terminal, which enables a simple and cost-effective production of the pole terminal with the tongues.

In a preferred exemplary embodiment of the invention, at least one of the tongues of the pole terminal is electrically conductive outwardly in order to electrically contact a connection part of the current-sense resistor, in particular through welding or soldering of the relevant tongue with the connection part of the current-sense resistor. This tongue therefore has a mechanical and electrical double function in that the tongue is used on the one hand for mechanically holding the current-sense resistor and on the other hand also effects an electrical contacting of the current-sense resistor.

In the preferred exemplary embodiment of the invention, at least one of the tongues of the pole terminal is furthermore outwardly electrically insulated in order to prevent electrical contact of this tongue to the current-sense resistor, as this otherwise would lead to an electrical short circuit over the current-sense resistor. This electrically insulated tongue of the pole terminal is therefore only used for mechanically holding the current-sense resistor and otherwise has no electrical contacting function.

In the preferred exemplary embodiment of the invention, the pole terminal has at least two such electrically insulated tongues which grip the current-sense resistor at the upper side and at the underside. This is advantageous because a power connection cable is generally connected at the connection part of the current-sense resistor which is not contacted by the pole terminal, so that considerable forces can act at this connection part of the current-sense resistor. If the forces acting on the free connection part are upwardly directed, then these forces are absorbed and mechanically dissipated by the tongue of the pole terminal arranged at the upper side of the current-sense resistor. If the forces acting on the free connection part of the current-sense resistor are by contrast downwardly directed, then these forces are absorbed and dissipated by the tongue arranged at the underside of the current-sense resistor.

Furthermore, the battery sensor according to the invention preferably also has an integrated electronic measuring circuit which measures the electric voltage dropping over the current-sense resistor as a measure for the battery current. For example, a measuring circuit, as is described in EP 1 030 185 A2 or EP 1 363 131 A1, can be used for this. With regards to the design of the measuring circuit, the invention is not limited to the measuring circuits which are described in the previously mentioned publications however.

In the preferred exemplary embodiment of the invention, the battery sensor has a circuit board for accommodating the electronic measuring circuit, wherein the circuit board is preferably arranged directly on the current-sense resistor.

On the one hand, this direct arrangement of the circuit board with the measuring circuit on the current-sense resistor is advantageous, because as a result, a stable design and very low inductance can be achieved.

On the other hand, in this manner a good thermal contact between the circuit board and the current-sense resistor can be achieved, as a result of which the disturbing influence of thermoelectric voltage can be minimized.

In the preferred exemplary embodiment of the invention, the circuit board has voltage taps on the underside thereof, in order to measure the electric voltage over the current-sense resistor, wherein the two voltage taps of the circuit board are electrically connected to two connection parts of the current-sense resistor, in particular by means of soldering. The measuring circuit (e.g. ASIC: Application Specific Integrated Circuit) is here preferably arranged on the upper side of the circuit board, however an arrangement of the measuring circuit on the underside of the circuit board is alternatively also possible, however.

The power supply of the battery sensor and in particular of the measuring circuit integrated into the battery sensor, preferably takes place via an electric voltage input, by means of which a supply voltage is fed in, wherein this is generally the battery voltage. Furthermore, the battery sensor can then also measure the supply voltage by means of the measuring circuit. The battery sensor according to the invention therefore makes not only a measurement of the battery current, but also a measurement of the battery voltage possible in the preferred exemplary embodiment.

Furthermore, the battery sensor according the invention preferably has a data output, in order to be able to output measured values (e.g. battery current, battery voltage, etc.) via the data output.

In the preferred exemplary embodiment, the data output and the voltage input are realized in the same plug contact, as a result of which the electrical contacting of the battery sensor is facilitated.

The data output preferably offers a digital data bus, such as for example a CAN bus (CAN: Controller Area Network) or a LIN bus (LIN: Local Interconnect Network). With respect to the data structure at the data output, the invention is not limited to these bus types, but can also be realized with other parallel or serial bus types.

Further, the battery sensor according the invention preferably also has a temperature measuring device which can measure various temperatures or temperature differences.

On the one hand, the temperature measuring device can measure the temperature of the current-sense resistor in order to be able to take account of temperature-related fluctuations of the resistance value of the current-sense resistor during the measurement of the battery current. This is advantageous, because during the calculation of the battery current in accordance with Ohm's law, the resistance value of the current-sense resistor is assumed to be known.

On the other hand, the temperature measuring device can measure the temperature difference between the connection parts of the current-sense resistor. This is advantageous, because a slight thermoelectric voltage can arise in the case of such a temperature difference, which thermoelectric voltage distorts the voltage measurement and therefore also the measurement of the battery current. By measuring this temperature difference, the thermoelectric voltage can then be calculated and taken into account in a compensatory manner during the measurement of the battery current.

In the preferred exemplary embodiment of the invention, the battery sensor has an electrically insulating plastic sheathing, which partially or completely sheathes the current-sense resistor, the circuit board, the measuring circuit, the plug contact, the temperature measuring device and/or the tongues of the pole terminal.

In the preferred exemplary embodiment of the invention, the plastic sheathing is used together with the tongues for mechanically holding the current-sense resistor. The tongues therefore fulfill their mechanical stabilization function only in connection with the plastic sheathing. The tongues themselves therefore do not have to rest directly on the current-sense resistor in order to to be able to hold the current-sense resistor. In the context of the invention, there is also the possibility however that the tongues rest directly on the current-sense resistor and therefore mechanically hold the current-sense resistor independently of the plastic sheathing.

This plastic sheathing preferably consists of a duroplastic which is advantageous for various reasons. On the one hand, duroplastic adheres well to metal, as a result of which the production is facilitated. On the other hand, duroplastic is moisture-proof even at transition points between the duroplastic and the metal of the current-sense resistor. A further advantage of duroplastic as material for the plastic sheathing consists in the fact that the thermal coefficient of expansion of duroplastic is adapted to the thermal coefficient of expansion of metal, so that no thermal problems arise in the event of temperature changes. Furthermore, duroplastic is also more mechanically loadable than other plastics, as a result of which the mechanical loadability of the battery sensor according to the invention is further improved. Furthermore, duroplastic is exceptionally thin during overmolding and does not damage electronic components, which is not the case in the case of thermoplastics for example. Finally, duroplastic enables a simple production in that the plastic sheathing is simply overmolded.

With regards to the material of the plastic sheathing, the invention is not limited to duroplastic however, but rather can fundamentally also be realized with other plastics which are preferably thermally conductive and preferably have the same thermal expansion properties as the circuit board, the current-sense resistor and/or the measuring circuit.

Further, it is to be mentioned that the current-sense resistor in the preferred exemplary embodiment protrudes to some extent out of the plastic sheathing by means of one of the two plate-shaped connection parts thereof, and with the protruding part forms a power connection in order to conduct the battery current in or out.

Furthermore, it is to be mentioned that the invention is not limited to the previously described battery sensor according to the invention as a single component but rather also comprises a battery, on which a battery sensor according to the invention is mounted.

Other advantageous developments of the invention are characterized in the subclaims or are explained in more detail below together with the description of the preferred exemplary embodiment of the invention on the basis of the figures. The figures show as follows:

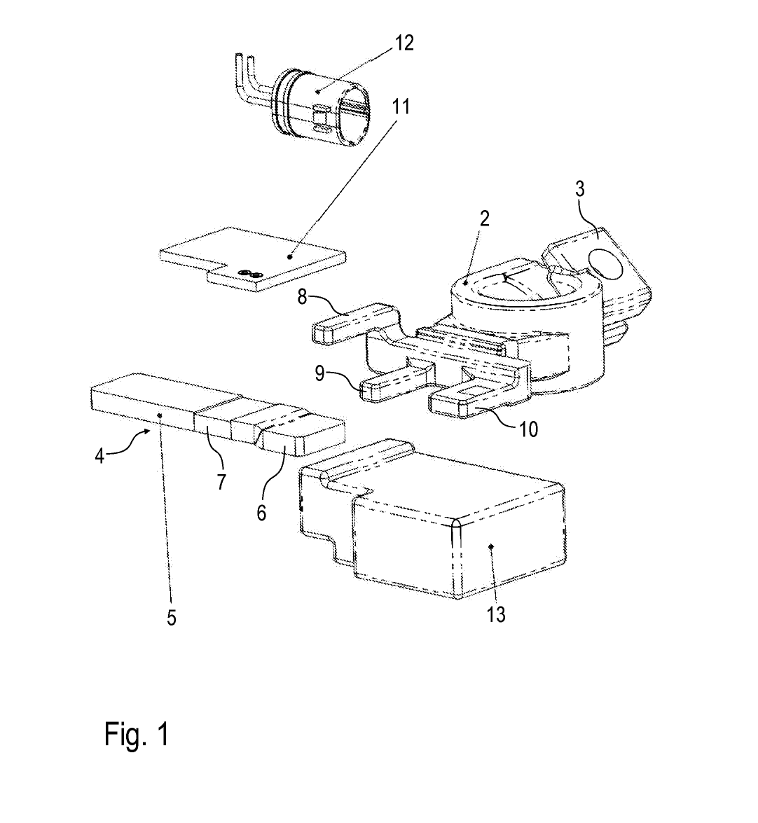

FIG. 1 an exploded illustration of a battery sensor according to the invention,

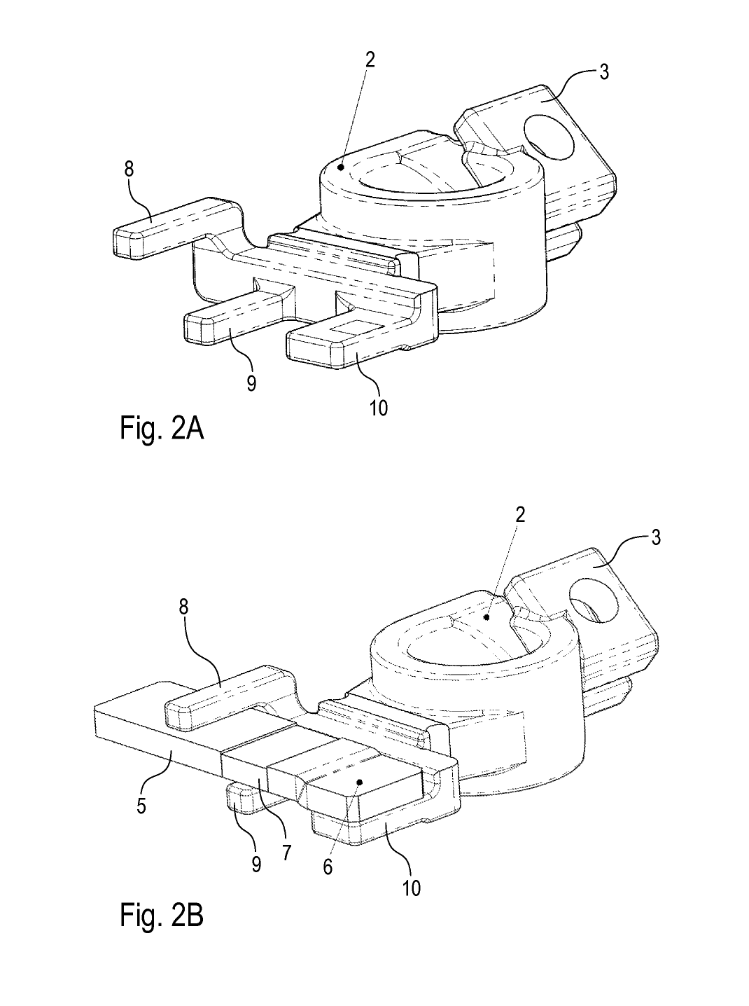

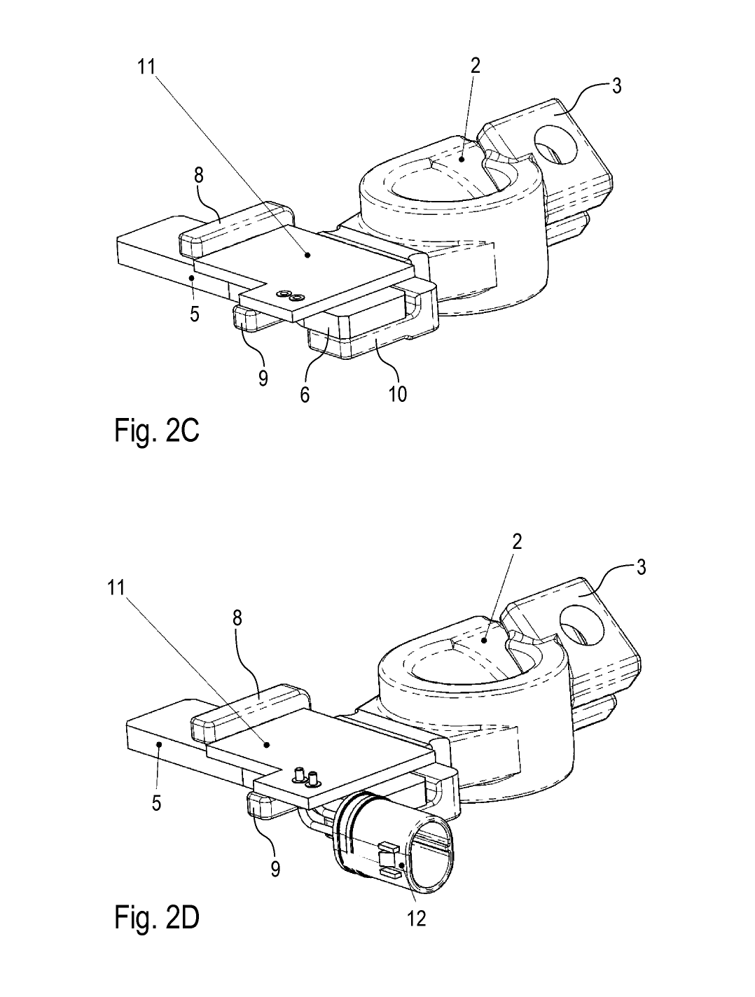

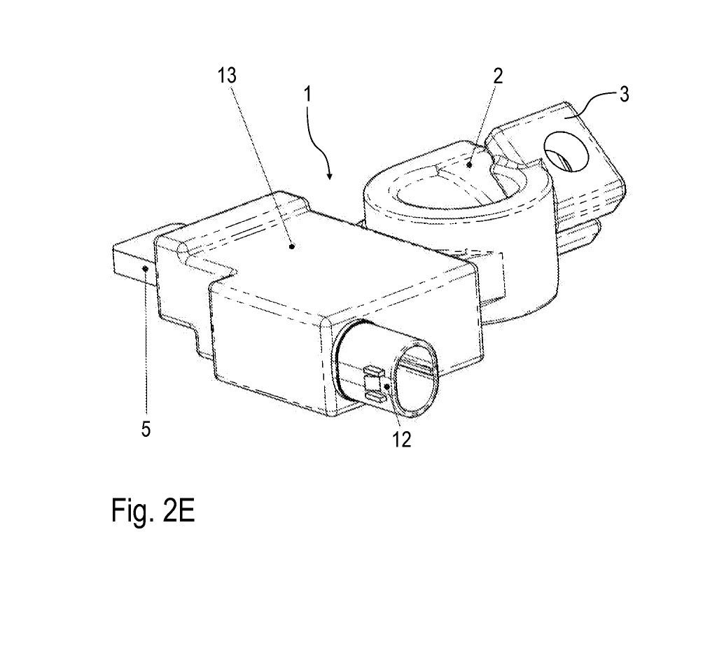

FIG. 2A a perspective view of a pole terminal of the battery sensor according to the invention,

FIG. 2B a perspective view of the pole terminal according to FIG. 2 with the current-sense resistor already mounted therein,

FIG. 2C a perspective view of a further assembly step with the circuit board with a measuring circuit already arranged on the current-sense resistor,

FIG. 2D a further assembly step with a plug contact connected to the circuit board, and also

FIG. 2E a perspective view of a fully assembled battery sensor according to the invention.

The drawings show a battery sensor 1 according to the invention (cf. FIG. 2E), which can be used for measuring the battery current (charging current or discharge current) in a conventional motor vehicle battery.

To this end, the battery sensor 1 has a pole terminal 2 which for measuring the battery current is plugged onto the ground pole of the motor vehicle battery and then fastened by means of a screwed flange 3 on the ground pole, as a result of which an electrical and mechanical connection between the pole terminal 2 and the ground pole of the motor vehicle battery is produced.

The measuring of the battery currents takes place in accordance with known four-wire technology by means of a low-ohmic current-sense resistor 4, wherein the current-sense resistor 4 can be constructed in the conventional manner, as is described for example in EP 0 605 800 A1. Thus, the current-sense resistor 4 has two plate-shaped connection parts 5, 6 made of a conductor material (e.g. copper or a copper alloy) and a likewise plate-shaped resistance element 7 made of a very low-ohmic resistance alloy (e.g. Manganin®), wherein the resistance element 7 is arranged in the current path between the two connection parts 5, 6, so that the battery current is conducted via the two connection parts 5, into the current-sense resistor or conducted out of the same and flows through the low-ohmic resistance element 7. The voltage drop over the low-ohmic resistance element 7 thus corresponds in accordance with Ohm's law to the battery current which flows through the current-sense resistor 4.

The pole terminal 2 has three tongues 8, 9, 10 for mechanically holding the current-sense resistor 4 on the pole terminal 2, which tongues are integrally molded onto the pole terminal 2 and laterally protrude from the pole terminal 2 parallel to one another.

The tongue 10 is used here not only for mechanically holding the current-sense resistor 4, but also for electrically contacting the connection part 6 of the current-sense resistor 4, as can be seen from FIG. 2B in particular.

Thus, the connection part 6 of the current-sense resistor 4 in the assembled state is connected by means of a soldered connection to the tongue 10 of the pole terminal 2. To enable this electrical contacting, the pole terminal 2 and thus also the tongue 10 consists of an electrically conductive material (e.g. brass), wherein the tongue 10 is not outwardly insulated in order to enable the electrical contacting of the connection part 6. The tongue 10 therefore has a double function in this exemplary embodiment. On the one hand, the tongue 10 supports the current-sense resistor 4 below the connection part 6 and is thus used for mechanically holding the current-sense resistor 4. On the other hand, the tongue is however also used for electrically contacting the current-sense resistor 4.

The two other tongues 8, 9 of the pole terminal 2 are used by contrast exclusively for mechanically holding the current-sense resistor 4. Thus, the tongue 9 supports the current-sense resistor 4 at the underside thereof, whilst the other tongue 8 rests on the upper side of the current-sense resistor 4, so that the two tongues 8, 9 grip the current-sense resistor 4 on the upper side or on the underside.

It can furthermore be seen from FIGS. 2C and 2D that a circuit board 11 with a measuring circuit (not illustrated) is arranged on the upper side of the current-sense resistor, wherein the circuit board 11 has two voltage taps on the underside thereof, which are connected by means of a soldered connection to the two connection parts 5, 6 of the current-sense resistor 4, so that the voltage taps of the circuit board 11 measure the voltage drop over the resistance element 7. The measuring circuit arranged on the upper side of the circuit board 11 is connected via corresponding conductor tracks to these two voltage taps and thus measures the voltage drop over the resistance element 7 of the current-sense resistor 4. Furthermore, the circuit board 11 also has a ground contact which is not illustrated.

Further, the battery sensor 1 according to the invention has a plug contact 12 which has two functions.

On the one hand, the battery voltage of the motor vehicle battery is supplied via the plug contact 12, which battery voltage is likewise measured by the measuring circuit arranged on the circuit board 11 and is also used for the supplying power to the battery sensor 1.

On the other hand, the plug contact 12 also has a data output in the form of a CAN bus (CAN: Controller Area Network) or a LIN bus (LIN: Local Interconnect Network), in order to be able to output the data measured by the measuring circuit.

Furthermore, of particular importance is a plastic sheathing 13 made of duroplastic, which sheathes the current-sense resistor 4, the tongues 8-10, the circuit board 11 and the interior of the plug contact 12.

On the one hand, the plastic sheathing is used for electrically insulating and hermetically sealing the battery sensor 1 outwardly.

On the other hand, the plastic sheathing 13 is however also used for mechanically stabilizing the battery sensor 1. Thus, the connection part 5 of the current-sense resistor 4 projects out of the plastic sheathing 13, so that the mechanical forces acting on the connection part 5 are not only absorbed by the two tongues 8, 9, but also by the plastic sheathing 13 which thus likewise contributes to the mechanical stabilization. Furthermore, the plastic sheathing 13 fills the intermediate space between the tongues 8, 9 on the one hand and the current-sense resistor 4 on the other hand, so that the tongues 8, 9 can mechanically stabilize the current-sense resistor 4.

Further, it is to be mentioned that the measuring circuit arranged on the circuit board 11 also measures the temperature difference between the two connection parts 5, 6 of the current-sense resistor 4. This is advantageous, as in this manner thermoelectric voltages, which arise due to a temperature difference between the two connection parts 5, 6 of the current-sense resistor, can be compensated.

Furthermore, the temperature measuring device arranged on the circuit board 11 also measures the temperature of the current-sense resistor 4 This makes sense, because the resistance value of the resistance element 7 of the current-sense resistor 4 fluctuates slightly with the temperature. By measuring the temperature of the resistance element 7, these temperature-related fluctuations of the resistance value can be taken into account and compensated during the measurement of the battery current.

The invention is not limited to the previously described preferred exemplary embodiment. Instead, a plurality of variants and modifications are possible, which also make use of the concept of the invention and thus fall within the scope of protection. Furthermore the invention also claims protection for the subject-matter and the features of the subclaims independently of the features of the claims to which they refer. Thus, for example the idea of a plastic sheathing in the context of the invention has an importance worthy of protection of its own.

1 Battery sensor

2 Pole terminal

3 Screwed flange

4 Current-sense resistor

5 Connection part

6 Connection part

7 Resistance element

8 Tongue

9 Tongue

10 Tongue

11 Circuit board

12 Plug contact

13 Plastic sheathing

1-15. (canceled)

16. A battery sensor for a battery comprising:
a) a pole terminal comprising an electrically conductive material for electric connection of the battery sensor to a connecting contact of a battery;
b) a low-ohm current-sense resistor for measurement of a battery current with which the battery is discharged or charged; and
c) a plurality of tongues protruding from the pole terminal for mechanical mounting of the current-sense resistor on the pole terminal.

17. The battery sensor according to claim 16, wherein the tongues are formed in one piece on the pole terminal.

18. The battery sensor according to claim 16, wherein at least one of the tongues of the pole terminal is electrically conductive outwardly in order to electrically contact a connection part of the current-sense resistor.

19. The battery sensor according to claim 16, wherein at least one of the tongues of the pole terminal is electrically insulated outwardly in order to avoid any electric contact with the current-sense resistor.

20. The battery sensor according to claim 19, wherein two tongues of the pole terminal are outwardly electrically insulated and grip the current-sense resistor on an upper side and on an underside thereof.

21. The battery sensor according to claim 16, further comprising an electronic measuring circuit for measuring an electric voltage dropping over the current-sense resistor as a measure for the battery current.

22. The battery sensor according to claim 21, further comprising a circuit board, wherein the circuit board:
a) is adapted to receive the electronic measuring circuit;
b) is arranged directly on the current-sense resistor; and
c) has voltage taps on an underside thereof, in order to measure electric voltage over the current-sense resistor, wherein two voltage taps of the circuit board are electrically connected to two connection parts of the current-sense resistor.

23. The battery sensor according to claim 22, wherein the measuring circuit is arranged on an upper side of the circuit board.

24. The battery sensor according to claim 21, wherein
a) the battery sensor has an electric voltage input for supplying a supply voltage;
b) the measuring circuit is supplied with electrical energy by the supply voltage supplied via the voltage input; and
c) in addition to the battery current, the measuring circuit also measures the supply voltage fed in via the voltage input.

25. The battery sensor according to claim 16, wherein the battery sensor further comprises a data output for outputting of measured values.

26. The battery sensor according to claim 25, wherein the data output and the voltage input are realized within a same plug contact.

27. The battery sensor according to claim 25, wherein the data output offers a digital data bus.

28. The battery sensor according to claim 16, further comprising a temperature measuring device for measuring at least one of a temperature of the current-sense resistor and a temperature difference between connection parts of the current-sense resistor.

29. The battery sensor according to claim 28, wherein the measuring circuit calculates a thermoelectric voltage dropping over the current-sense resistor as a function of the measured temperature difference over the current-sense resistor and takes account of the thermoelectric voltage in the measurement of the battery current.

30. The battery sensor according to claim 28, wherein the measuring circuit calculates a thermally induced change in resistance as a function of the measured temperature of the current-sense resistor and takes account of the thermally induced change in resistance in the measurement of the battery current.

31. The battery sensor according to claim 16, further comprising an electrically insulating plastic sheathing, which sheaths at least one of the current-sense resistor, a circuit board, a measuring circuit, a plug contact, a temperature measuring device and the tongues of the pole terminal.

32. The battery sensor according to claim 31, wherein the plastic sheathing consists of a thermosetting plastic.

33. The battery sensor according to claim 31, wherein the current-sense resistor, the circuit board, the measuring circuit, the plug contact, the temperature measuring device and the tongues of the pole terminal are coated with a thermosetting plastic.

34. The battery sensor according to claim 31, wherein the plastic sheathing consists of a plastic, which has essentially the same thermal expansion behavior as the circuit board.

35. The battery sensor according to claim 31, wherein the plastic sheathing consists of a plastic, which is thermally conductive.

36. The battery sensor according to claim 31, wherein the current-sense resistor protrudes to some extent out of the plastic sheathing by way of one of two connection parts thereof, and with a protruding part forms a power connection in order to conduct the battery current in or out.

37. The battery sensor according to claim 16, wherein
a) the current-sense resistor has a first plate-shaped connection part comprising a conducting material and a second plate-shaped connection part comprising the conducting material;
b) the current-sense resistor has a plate-shaped resistance element comprising a resistance alloy;
c) the resistance element is arranged in a current path between both connection parts; and
d) the conductor material has a smaller specific electric resistance than the resistance alloy.

38. The battery sensor according to claim 37, wherein
a) a first tongue of the pole terminal mechanically supports the first connection part of the current-sense resistor from below;
b) the first tongue of the pole terminal electrically contacts the first connection part of the current-sense resistor;
c) the second connection part of the current-sense resistor forms a current connection in order to lead in or to lead out the battery current;
d) a second tongue of the pole terminal supports the current-sense resistor from below;
e) a third tongue of the pole terminal supports the current-sense resistor from above;
f) the second tongue and the third tongue of the pole terminal are outwardly electrically insulating in order to avoid any electric contact with the current-sense resistor; and
g) the second tongue and the third tongue support the current-sense resistor between the two connection parts, in order to absorb a mechanical loading at the second connection part used as power connection.

39. A battery with two connecting contacts, wherein a battery sensor according to claim 16 is attached to one of the connecting contacts.
